(19) United States
(12) Patent Application Publication
(10) Pub. No.: US 2017/0229096 A1
(43) Pub. Date: Aug. 10, 2017

(54) LIGHT-EMITTING MODULE AND LIGHT-EMITTING DISPLAY PANEL

(71) Applicant: OPTO TECH CORPORATION, HSINCHU COUNTY (TW)

(72) Inventors: KUO-SHU HUANG, HSINCHU (TW); CHIA-SHEN TENG, HSINCHU (TW); CHEUK-WAI LAU, HSINCHU (TW); SHANG-CHIEN WU, HSINCHU (TW); KAO-NAN CHEN, HSINCHU (TW)

(21) Appl. No.: 15/334,529

(22) Filed: Oct. 26, 2016

(30) Foreign Application Priority Data
Feb. 5, 2016 (TW) 105202152

(51) Int. Cl. G09G 5/02; G09G 5/10; H01L 27/15

(52) U.S. Cl. CPC G09G 5/02; H01L 27/15; G09G 5/10; G09G 2310/08; G09G 2380/02

(57) ABSTRACT

The present invention relates to a light-emitting module and a light-emitting display panel. The light-emitting module comprises a substrate, one ore more light-emitting unit, and a driving unit. The substrate comprises a power input, a ground, a data input, a data output, a clock input, and a clock output. The one or more light-emitting unit is disposed on the substrate. The driving unit is connected electrically to the data input, the clock input, and the power input, respectively, and controls the color-scale changes of the light-emitting unit. A plurality of light-emitting modules are disposed on the circuit board. The control signal controlling the plurality of light-emitting modules is transmitted in series. It isn't required to connect the plurality of light-emitting module to additional connecting wires for signal control. Accordingly, shading of the light passing through the display panel and inferior transmittance due to excess electrical connecting wires may be prevented.

### FIELD OF THE INVENTION

The present invention relates generally to a module and a panel, and particularly to a light-emitting module and a light-emitting display panel.

### BACKGROUND OF THE INVENTION

Technologies advance with each passing day. In big cities, there are tall buildings and great mansions of various kinds. They become common scenes in big cities. Nowadays, in addition to practicality, the standard of aesthetics for the buildings has set higher increasingly. Modern buildings provide not only residence or working. They may become landmarks of modern cities. Currently, considering aesthetics and the needs for natural light, more buildings abandon traditional concrete walls. Instead, transparent glass curtain walls are adopted. In this way, the appearance will look neat and eye-appealing, unlike the cold and rough appearance of traditional concrete walls. In order to increase the added values of buildings, large display panels start to appear on the outer walls of the buildings at good locations. It has become a technique of novel advertisements and a trend for promotion.

The fabrication method for the large display panels as described above is to make use of LEDs, which are disposed in arrays on the inner surface of glass curtain walls. In general, LED arrays are disposed on printed circuit boards. Nonetheless, printed circuit boards are opaque, resulting in difficulties in guiding the natural light by the glass curtain walls. In addition, the plurality of LED chips are disposed on printed circuit boards. The plurality of LED chips require multiple electrical connecting wires, respectively, for supplying power and controlling. The electrical connecting wires are opaque. Massive wires are disposed on the display panel. Thereby, light cannot pass through the display panel, and the transmittance of the display panel become inferior.

Nowadays, high-performance power-saving glass green building materials are advocated. By using them, the exterior heat may be prevent from entering a building and thus achieving the purposes of saving power and improving living quality. In addition to considering the power consumption for air conditioning by using glass building materials as the outer covering of a building, the power consumption for lighting and the influence of light pollution on the surroundings should be regulated. The transmittance of visible light is defined as the ratio of the visible light passing through glass building materials and entering a building to the visible light in sunlight. Higher transmittance of visible light represents higher efficacy of converting sunlight to effective indoor lighting. The transmittance of visible light for high-performance power-saving glass green building materials is regarded not smaller than 0.5.

Accordingly, the present invention improves the drawbacks in the prior art as described above and provides a light-emitting module and a light-emitting display panel. The light-emitting module comprises a driving unit and one or more light-emitting unit. The driving unit controls the color-scale changes of the one or more light-emitting unit. In addition, a plurality of light-emitting modules are connected electrically. The electrical connecting wires pass inside the plurality of light-emitting modules and reducing massive electrical connecting wires exposed to the display panel. Thereby, the drawback of shading of the light passing through the display panel by the massive wires, which leads to inferior transmittance, may be prevented.

### SUMMARY

An objective of the present invention is to provide a light-emitting module and a light-emitting display panel, which may control the color-scale changes of individual light-emitting module.

Another objective of the present invention is to provide a light-emitting module and a light-emitting display panel, which reduces massive electrical connecting wires exposed to the display panel for preventing shading of the light passing through the display panel by the massive wires. Thereby, the drawback of inferior transmittance may be improved.

The present invention provides a light-emitting module, which comprises a substrate, one ore more light-emitting unit, and a driving unit. The substrate comprises a data input, a clock input, and a power input. The one or more light-emitting unit is disposed on the substrate. The driving unit is connected electrically to the data input, the clock input, and the power input, and controls the color-scale changes of the one ore more light-emitting unit.

According to an embodiment of the present invention, the substrate further comprises a data output, a clock output, and a ground.

According to an embodiment of the present invention, the one or more light-emitting unit is selected from the group consisting of red LED chip, green LED chip, blue LED chip, invisible-light LED chip, and laser chip.

According to an embodiment of the present invention, the material of the substrate is a transparent, translucent, or low reflective material.

According to an embodiment of the present invention, the present invention further comprises a reflective frame disposed at the substrate. The reflective frame includes a hole. The one ore more light-emitting unit and the driving unit are disposed in the hole. A packaging gel fills the hole and covers the one ore more light-emitting unit and the driving unit.

According to an embodiment of the present invention, the present invention further includes a packaging gel covering the one ore more light-emitting unit and the driving unit and disposed on the substrate.

The present invention provides a light-emitting display panel, which comprises a circuit board, and a plurality of light-emitting modules. The circuit board comprises a board body, a plurality of first electrical connecting wires, a plurality of second electrical connecting wires, and a plurality of transparent parts. Each first electrical connecting wire corresponds to each second electrical connecting wire and forming an electrical connecting bus terminal on the corresponding ends. Each first electrical connecting wire comprises a first power connecting wire, a first ground connecting wire, a first data connecting wire, and a first clock connecting wire. Each second electrical connecting wire comprises a second power connecting wire, a second ground connecting wire, a second data connecting wire, and a second clock connecting wire. The plurality of electrical connecting bus terminals are disposed on the board body and located between the plurality of transparent parts. Besides, each light-emitting module comprises a power input, a ground, a data input, a data output, a clock input, and a clock output. The plurality of light-emitting modules are connected electrically to the electrical connecting bus terminals.

According to an embodiment of the present invention, the power input of each light-emitting module is connected electrically to the first power connecting wire and the second electrical connecting wire. The ground of each light-emitting module is connected electrically to the first ground connecting wire and the second electrical connecting wire. The data input of each light-emitting module is connected to the first data connecting wire. The data output of each light-emitting module is connected to the second data connecting wire. The clock input of each light-emitting module is connected to the first clock connecting wire. The clock output of each light-emitting module is connected to the second clock connecting wire.

According to an embodiment of the present invention, the present invention further comprises a display frame used for fixing the light-emitting display panel. The display frame comprises a main module, a control module, and a fixing module. The main module comprises a post member, a first connecting end, and a second connecting end. The first connecting end and the second connecting end are disposed on both ends of the post member. The control module is disposed inside the post member and connected electrically to the first and second connecting ends. The fixing module is disposed on one side of the main module and comprises a fixing post member, a top frame, and a bottom frame. The fixing post member is disposed on one side of the post member. The top and bottom frames fix both ends of the fixing post member, respectively. The light-emitting display panel is sandwiched between the top and bottom frames. The control module is connected electrically to the light-emitting display panel.

According to an embodiment of the present invention, the first connecting end of each display frame is connected to the second connecting end of the display frame above. In addition, the control module of the display frame is connected electrically to the control module of the display frame above.

According to an embodiment of the present invention, the circuit board is flexible.

### BRIEF DESCRIPTION OF THE DRAWINGS

FIG. 1 shows a schematic diagram of the light-emitting module according to an embodiment of the present invention;

FIG. 2 shows a stereoscopic diagram of the packaging type for the light-emitting module according to the first embodiment of the present invention;

FIG. 3 shows a stereoscopic diagram of the packaging type for the light-emitting module according to the second embodiment of the present invention;

FIG. 4A shows a planar view of the light-emitting display panel according to an embodiment of the present invention;

FIG. 4B shows an enlarged view of the region A on the front side of FIG. 4A;

FIG. 4C shows an enlarged view of the region B on the back side of FIG. 4A;

FIG. 5 shows a structural view of the display frame of the light-emitting display panel according to an embodiment of the present invention;

FIG. 6 shows an exploded view of the display frame of the light-emitting display panel according to an embodiment of the present invention; and

FIG. 7 shows an electrical connection diagram of the display frame of the light-emitting display panel according to an embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

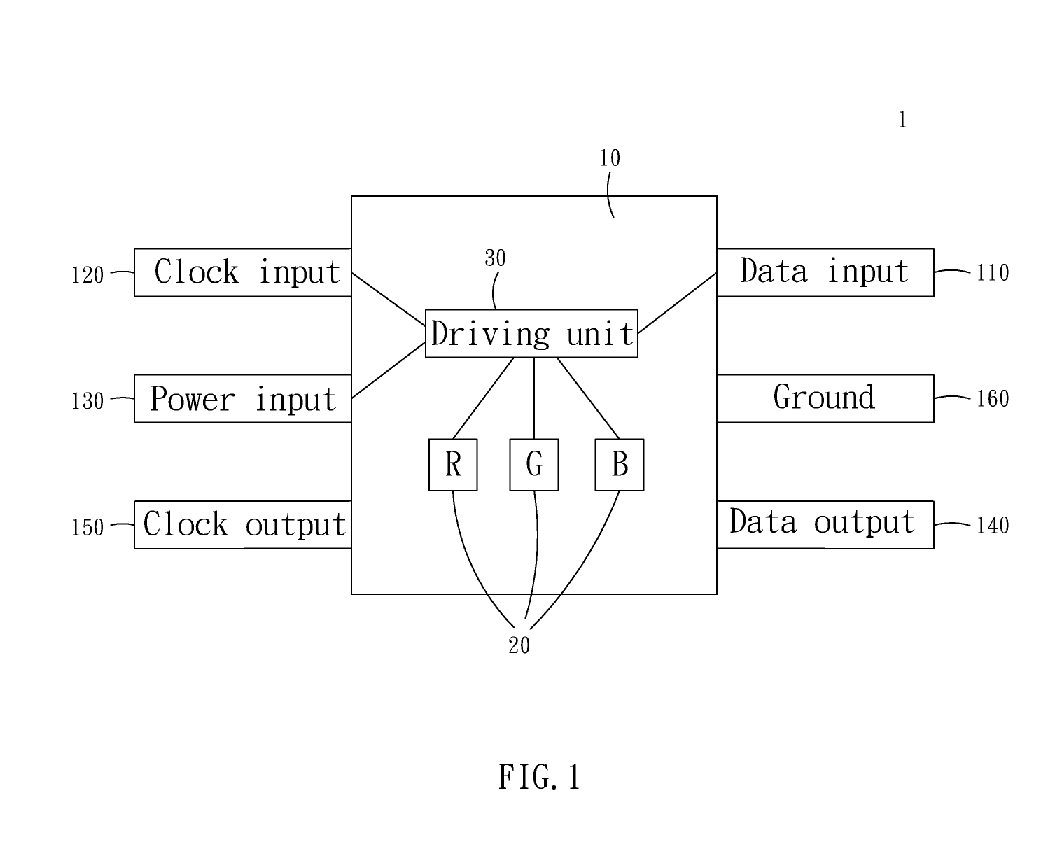

Please refer to FIG. 1, which shows a schematic diagram of the light-emitting module according to an embodiment of the present invention. As shown in the figure, the light-emitting module 1 according to the present embodiment comprises a substrate 10, one or more light-emitting unit 20, and a driving unit 30. The substrate 10 comprises a data input 110, a clock input 120, and a power input 130. The one or more light-emitting unit 20 is disposed on the substrate 10. The driving unit 30 is connected electrically to the data input 110, the clock input 120, and the power input 130. In addition, the driving unit 30 controls the color-scale changes of the one or more light-emitting unit 20. Thereby, the driving unit 30 is disposed in the light-emitting module 1 for controlling the color and brightness of the light emitted by the light-emitting module 1 and hence adjusting the details of the light.

The one ore more light-emitting unit 20 of the light-emitting module 1 is selected from the group consisting of red LED chip, green LED chip, blue LED chip, invisible-light (such as infrared or ultraviolet light) LED chip, and laser chip. In other words, in additional individual usage, any two of the chips described above may be mixed. For example, a red LED chip may be mixed with an invisible-light LED chip. Alternatively, any three of the chips as described above may be mixed as well. For example, a red LED chip, an invisible-light LED, and a laser chip may be mixed. Alternatively, any four of the chips as described may be mixed as well. The details will not be described further. Besides, according to the present embodiment, the most frequent combination of the LED chips is adopted. That is to say, a red LED chip, a green LED chip, and a blue LED chip are selected. Those colors are the three primary colors of light. By mixing the colors in different ratios, various colors of light may be generated. The driving unit 30 according to the present embodiment may work with various combinations of chips and thus achieving varied combinations of light.

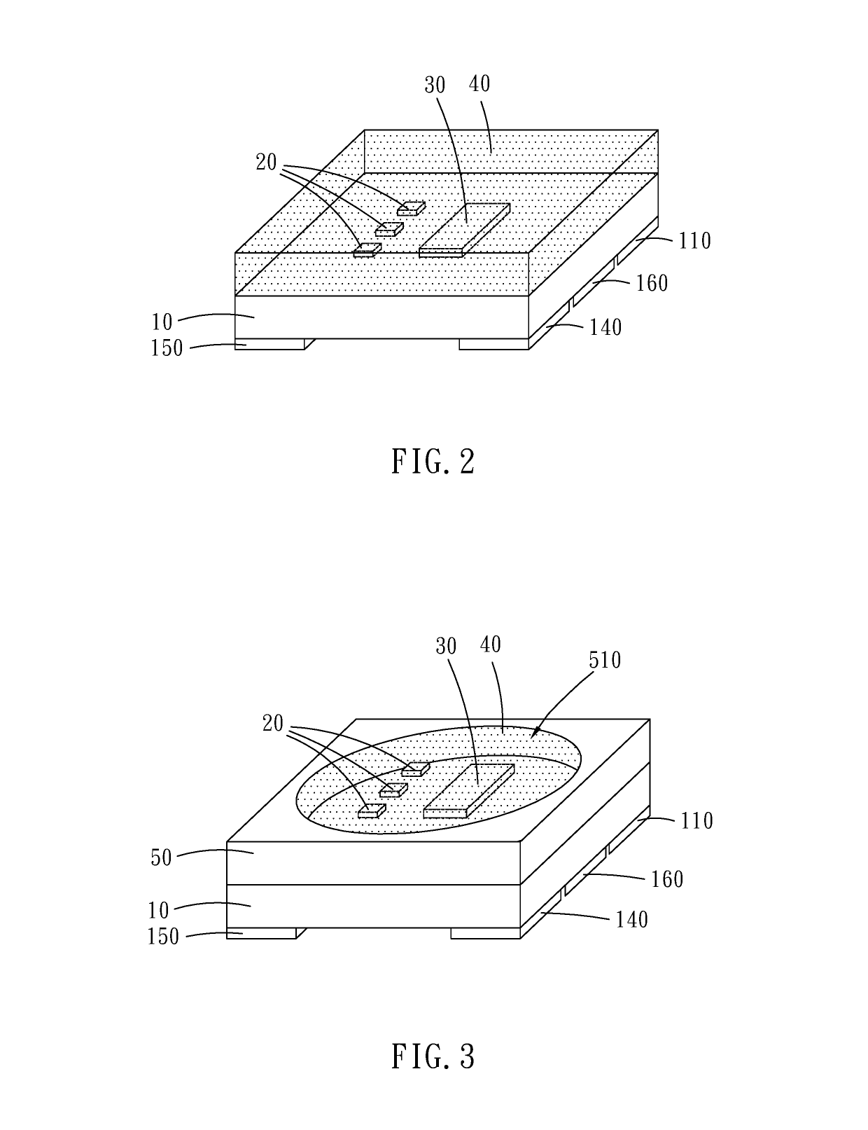

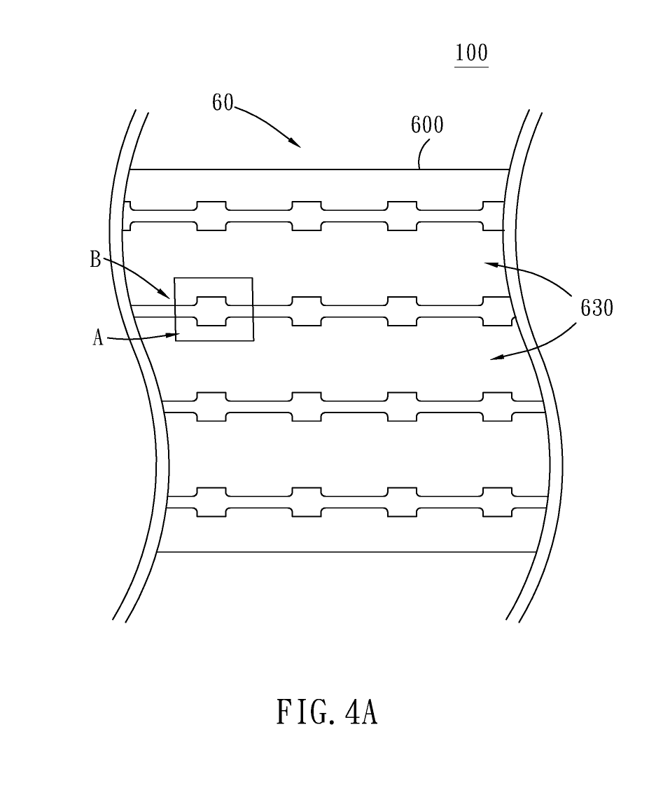

Please refer to FIG. 2 and FIG. 3, which show stereoscopic diagrams of the packaging types for the light-emitting module according to the first and second embodiments of the present invention. As shown in the figure, the present embodiments are used for describing the packaging types of two light-emitting modules. In the packaging type for LED in FIG. 2, the light-emitting module 1 further comprises a packaging gel 40 covering the one or more light-emitting unit 20 and the driving unit 30 and disposed on the substrate 10. In another packaging type for LED in FIG. 3, the light-emitting module 1 further comprises a reflective frame 50 disposed on the substrate 10. The reflective frame 50 includes a hole 510. The one or more light-emitting unit 20 and the driving unit 30 are located in the hole 510 and a packaging gel 40 fills the hole 510 and covers the one or more light-emitting unit 20 and the driving unit 30. The above two packaging types may be selected according to a user's requirement.

The present invention provides a light-emitting module 1, which includes the driving module 30 for adjusting the color-scale changes of the one or more light-emitting module 20. When multiple light-emitting modules 1 are disposed on the display panel, an external control module may be used for controlling the color-scale changes of the one or more light-emitting unit 20 of the multiple light-emitting modules 1. Thereby, various and changing combinations may be achieved, resulting in more light-emitting effects and flexible applications.

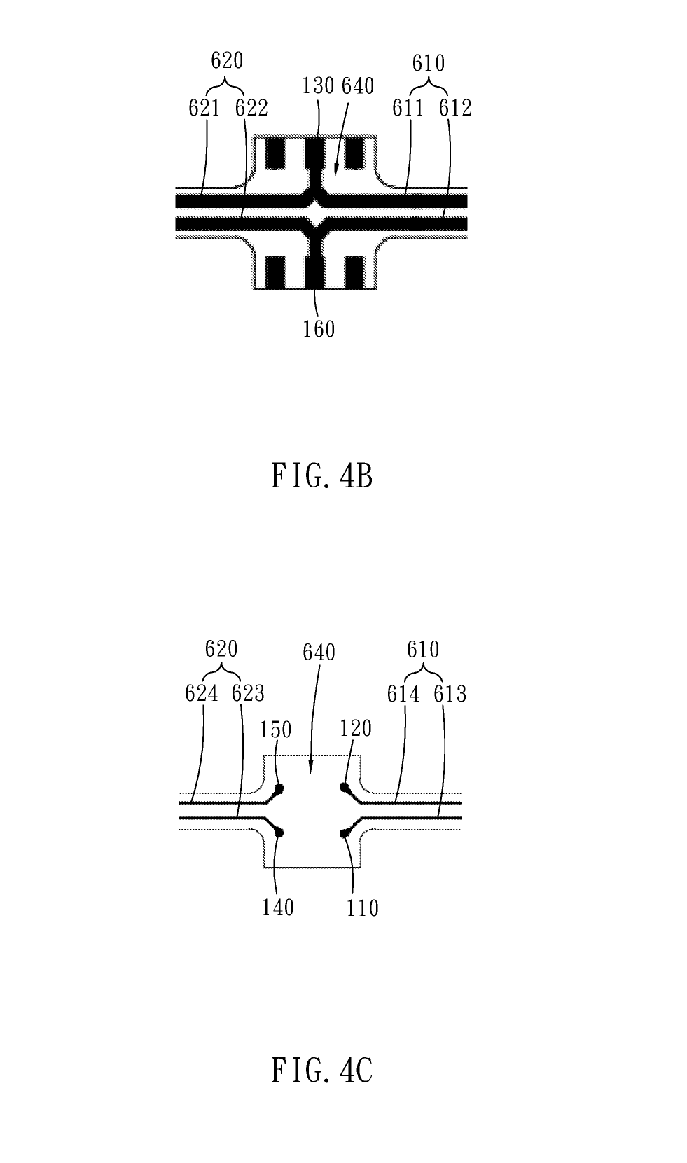

Please refer to FIGS. 4A to 4C, which show a planar view of the light-emitting display panel, an enlarged view of the region A on the front side of FIG. 4A, and an enlarged view of the region B on the back side of FIG. 4A according to an embodiment of the present invention. As shown in the figures, according to the present embodiment, a plurality of light-emitting modules 1 are disposed on a circuit board 60 and forming a light-emitting display panel 100. In the figures, the connection of the power, data, or clock connecting wires on the front and back sides are described. Please refer again to FIG. 1. The substrate 10 of the light-emitting module 1 according to the present embodiment further comprises a data output 140, a clock output 150, and a ground 160. The data input 110, the clock input 120, the power input 130, the data output 140, the clock output 150, and the ground 160 are disposed on both sides of the substrate 10. The clock input 120 is disposed opposing to the data input 110; the power input 130 is disposed opposing to the ground 160; and the clock output 150 is disposed opposing to the data output 140.

The circuit board 60 comprises a board body 600, a plurality of first electrical connecting wires 610, a plurality of second electrical connecting wires 620, and a plurality of transparent parts 630. Each first electrical connecting wire 610 corresponds to each second electrical connecting wire 620 and forming an electrical connecting bus terminal 640 on the corresponding ends. Each first electrical connecting wire 610 comprises a first power connecting wire 611, a first ground connecting wire 612, a first data connecting wire 613, and a first clock connecting wire 614. Each second electrical connecting wire 620 comprises a second power connecting wire 621, a second ground connecting wire 622, a second data connecting wire 623, and a second clock connecting wire 624. The plurality of electrical connecting bus terminals 640 are disposed on the board body 600 and located between the plurality of transparent parts 630. Then the plurality of light-emitting modules 1 are disposed to the plurality of electrical connecting bus terminals 640.

Please refer again to FIG. 4B. The power input 130 of each light-emitting module 1 is connected electrically to the first power connecting wire 611 and the second power connecting wire 621. Namely, the electrical positive terminal is connected to the other electrical positive terminal. The ground 160 of each light-emitting module 1 is connected electrically to the first ground connecting wire 612 and the second ground connecting wire 6221. Namely, the electrical negative terminal is connected to the other electrical negative terminal. Thereby, the power lines of the plurality of light-emitting modules 1 are connected in parallel. Consequently, the light-emitting module 1 located at the end will not suffer from insufficient power supply.

Please refer again to FIG. 4C. The data input 110 of each light-emitting module 1 is connected electrically to the first data connecting wire 613. The data output 140 of each light-emitting module 1 is connected electrically to the second data connecting wire 623. The clock input 120 of each light-emitting module 1 is connected electrically to the first clock connecting wire 614. The clock output 150 of each light-emitting module 1 is connected electrically to the second clock connecting wire 624. Thereby, the data transmission paths of the plurality of light-emitting modules 1 are connected in series and the clock transmission paths of the plurality of light-emitting modules 1 are connected in series, respectively. Accordingly, both the data signals and the clock signals of the plurality of light-emitting modules 1 are transmitted in serial streams, respectively.

According to the present embodiment, the plurality of light-emitting modules 1 are arranged on the board body 600. The first electrical connecting wires 610 and the second electrical connecting wires 620 are connected horizontally between the plurality of light-emitting modules 1, and thus enabling the plurality of light-emitting modules 1 in each row to receive identical power supplies and to transmit data and clock signals therebetween. The light-emitting modules 1 at the rear or the front end of every two adjacent rows are connected vertically, enabling the plurality of light-emitting modules 1 of adjacent rows to transmit data and clock signals to one another. Please refer again to FIG. 4A. The data and clock of the plurality of light-emitting modules 1 are connected in series in an S shape, respectively. Thereby, no extra connecting wires for data and clock control is required between the plurality of light-emitting modules 1 in each row. As a result, no connecting wire for data and clock transmission will shade the transparent parts 630 between the plurality of light-emitting modules 1 in each row. Light may thereby pass through the plurality of transparent parts 630.

Furthermore, the material of the substrate 10 of the plurality of light-emitting modules 1 is a transparent, translucent, or low-reflective material. As light passes through the light-emitting display panel 100, it will not be blocked by the plurality of light-emitting modules 1 of the light-emitting display panel 100. By taking advantage of the material of the substrate 10 of the light-emitting module 1, the factors of blocking or reflecting light are reduced. Besides, the circuit board 60 according to the present embodiment us flexible. Thereby, the light-emitting display panel 100 may be applied to planar or curved surfaces, enriching variations in applications.

The present embodiment improves the drawbacks in the prior art. According to the prior art, a plurality of LEDs are disposed on a display panel. If more complex controls are required for the display panel, for example, displaying characters or patterns, the plurality of LEDs need to be connected to control connecting wires, respectively, for controlling color or brightness changes of the plurality of LEDs. By using the above method, there will be excess wires around the control end of the display panel. The excess wires will shade a portion of light from passing through the display panel and hence reducing the transmittance thereof. Nonetheless, these display panels are applied to the exterior walls of a building. Considering the international markets, the performance of domestic glass building materials should be internationalized. There are the following regulations for glass green building materials. (1) Shading coefficient: A lower shading coefficient represents lower exterior heat energy entering a building, as a result of blocking by the glass building material. The shading coefficient of high-performance power-saving glass building material is regulated not higher than 0.35. (2) Visible-light reflectivity: It is the ratio of the light reflected by glass building materials to the visible light in the incident sunlight. If the visible-light reflectivity is higher, it means that the light pollution caused by the glass building materials is severer. The visible-light reflectivity of a high-performance power-saving glass green building material is regulated not to be greater than 0.25. (3) Visible-light transmittance: It is defined by the ratio of the light passing through glass building materials and entering the building to the visible light in the incident sunlight. If the ratio is higher, it means that the sunlight is converted to more effective indoor lighting. The visible-light transmittance of a high-performance power-saving glass green building material is regulated not to be smaller than 0.5. For the structures and technologies of the glass advertisement display panels according to the prior art on exterior walls of a building, the above regulations are difficult to be complied.

Accordingly, the present invention provides a light-emitting display panel 100. The advantage of the present invention is that each light-emitting module 1 of the light-emitting display panel 100 includes the driving unit 300. Each light-emitting module 1 may modify the color-scale changes via the driving unit 30. In addition, the light-emitting module 1 further includes the data input 110, the clock input 120, the power input 130, the data output 140, the clock output 150, and the ground 160. Thereby, the control signals that control the plurality of light-emitting modules 1 may be transmitted in series. Then the control signals will pass through the inside of the plurality of light-emitting modules 1, instead of requiring extra signal-control connecting wires for controlling the plurality of light-emitting modules 1. This method may reduce massive wires covering the light-emitting display panel 100. By covering, a portion of light is shaded or reflected by the massive wires and hence reducing the light capable of passing through the light-emitting display panel 100. Accordingly, the drawback of inferior light transmittance may be avoided and the related regulations for high-performance power-saving glass green building materials may be complied.

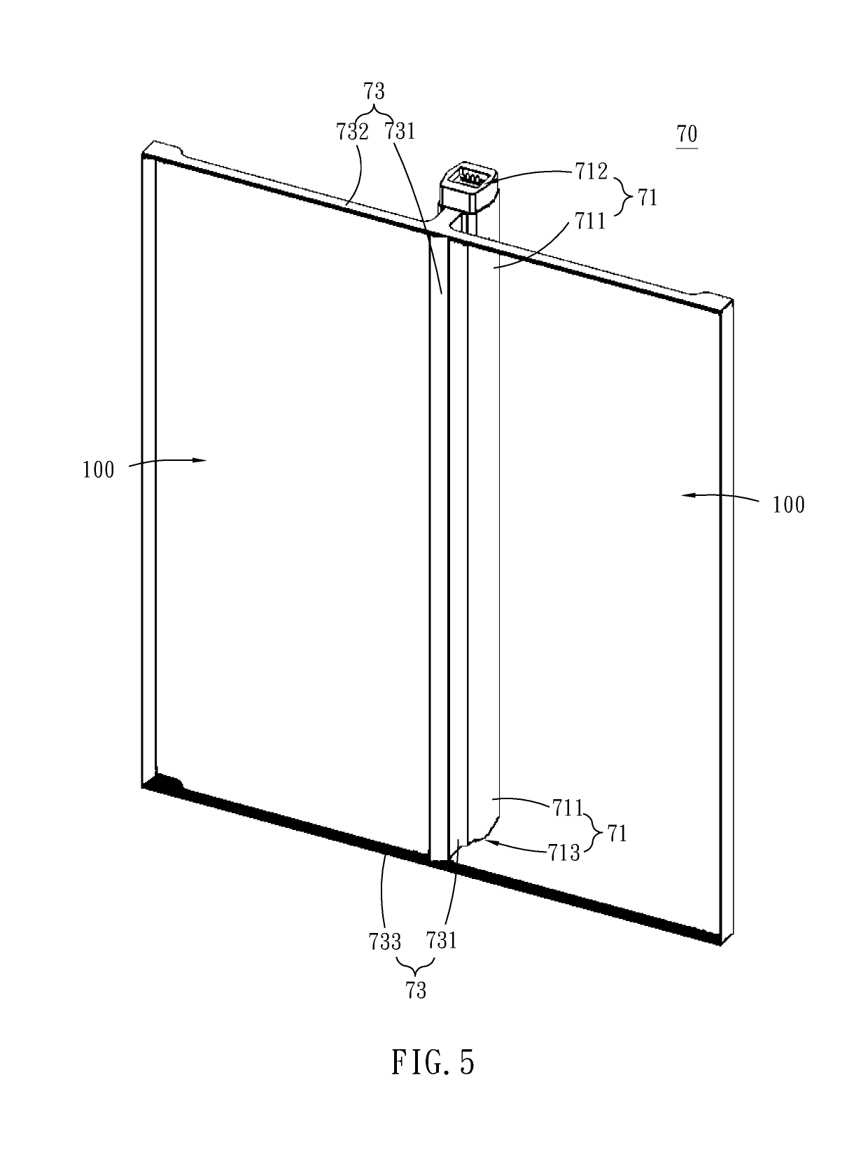

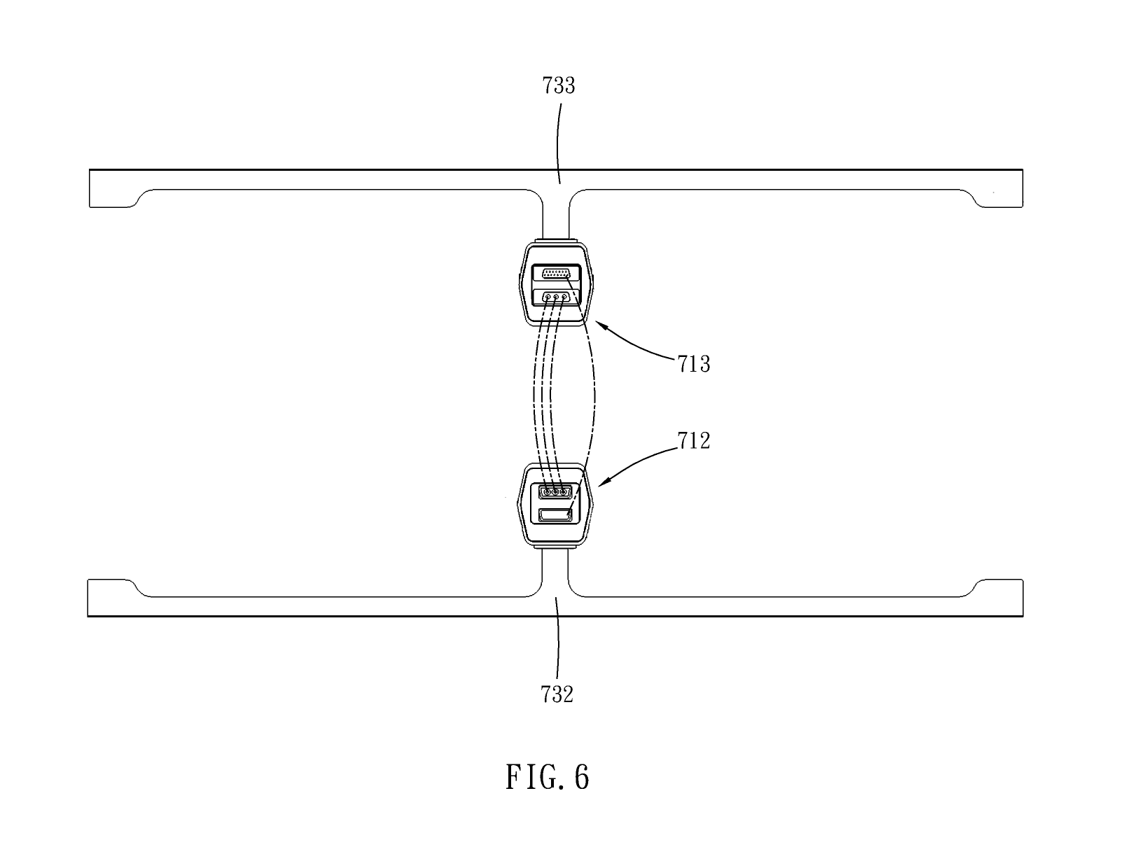

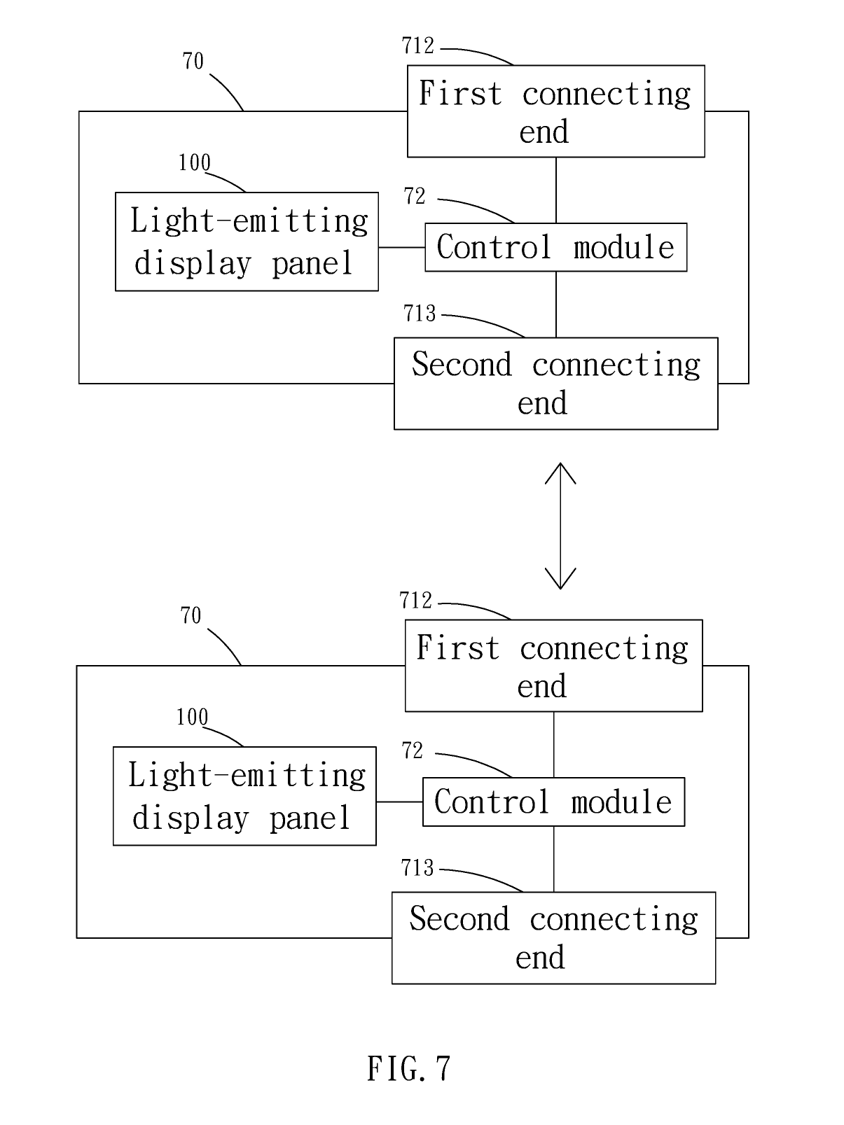

Please refer to FIGS. 5 to 7, which show a structural view, an exploded view, and an electrical connection diagram of the display frame of the light-emitting display panel according to an embodiment of the present invention. As shown in the figures, the present embodiment discloses a display frame 70, which is used for fixing the light-emitting display panel 100 and comprises a main module 71, a control module 72, and a fixing module 73. The main module comprises a post member 711, a first connecting end 712, and a second connecting end 713. The first connecting end 712 and the second connecting end 713 are disposed on both ends of the post member 711. The control module 72 is disposed inside the post member 711 and connected electrically to the first and second connecting ends 712, 713. The fixing module 73 is disposed on one side of the main module 71 and comprises a fixing post member 731, a top frame 732, and a bottom frame 733. The fixing post member 731 is disposed on one side of the post member 711. The top and bottom frames 732, 733 fix both ends of the fixing post member 731, respectively. The light-emitting display panel 100 is sandwiched between the top and bottom frames 732, 733. The control module 72 is connected electrically to the light-emitting display panel 100. The control module 72 includes a control unit and a power supply unit. It is connected electrically to the plurality of light-emitting modules 1 on the column close to the post member 711, and further connected to the data input 110, the clock input 120, and the power input 130, respectively. Thereby, the control module 72 may control each light-emitting module 1.

According to the present embodiment, the first connecting end 712 of each display frame 70 is connected to the second connecting end 713 of the display frame 70 above. In addition, the control module 72 of the display frame 72 is connected electrically to the control module 72 of the display frame 70 above. After the plurality of display frames 70 are connected electrically, the whole of the plurality of light-emitting display panels 100 may be controlled by the control module 72 of one of the plurality of light-emitting display panels 100.

To sum up, the present invention provides a light-emitting module and a light-emitting display panel. The light-emitting module may modify the color-scale changes of one or more light-emitting module. A plurality of light-emitting modules are disposed on a circuit board to form a light-emitting display panel. Each light-emitting module comprises a data input, a clock input, a power input, a data output, a clock output, and a ground. Thereby, the control signals that control the plurality of light-emitting modules may be transmitted in series. Then the control signals will pass through the inside of the plurality of light-emitting modules, instead of requiring extra signal-control connecting wires for controlling the plurality of light-emitting modules. This method may reduce massive wires covering the light-emitting display panel. By covering, a portion of light is shaded by the massive wires and hence reducing the light capable of passing through the light-emitting display panel. Accordingly, the drawback of inferior light transmittance may be avoided and the related regulations for high-performance power-saving glass green building materials may be complied, which is beneficial for entering the international market. Then the competitiveness of power-saving glass building materials may be reinforced.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A light-emitting module, comprising:
a substrate, comprising a data input, a clock input, and a power input;
one or more light-emitting unit, disposed on said substrate; and
a driving unit, connected electrically to said data input, said clock input, and said power input, respectively, and controlling the color-scale changes of said one or more light-emitting unit.

2. The light-emitting module of claim 1, wherein said substrate further comprises a data output, a clock output, and a ground.

3. The light-emitting module of claim 1, wherein said one or more light-emitting unit is selected from the group consisting of red LED chip, green LED chip, blue LED chip, invisible-light LED chip, and laser chip.

4. The light-emitting module of claim 1, wherein the material of said substrate is a transparent, translucent, or low reflective material.

5. The light-emitting module of claim 1, further comprising a reflective frame disposed on said substrate and including a hole, said one or more light-emitting unit and said driving unit located in said hole, and a packaging gel filling said hole and covering said one or more light-emitting unit and said driving unit.

6. The light-emitting module of claim 1, further comprising a packaging gel covering said one or more light-emitting unit and said driving unit and disposed on said substrate.

7. A light-emitting display panel, comprising:
a circuit board, comprising a board body, a plurality of first electrical connecting wires, a plurality of second electrical connecting wires, and a plurality of transparent parts, each said first electrical connecting wire corresponding to each said second electrical connecting wire and forming an electrical connecting bus terminal on the corresponding ends, each said first electrical connecting wire comprising a first power connecting wire, a first ground connecting wire, a first data connecting wire, and a first clock connecting wire, each second electrical connecting wire comprising a second power connecting wire, a second ground connecting wire, a second data connecting wire, and a second clock connecting wire, and said plurality of electrical connecting bus terminals disposed on said board body and located between said plurality of transparent parts; and
a plurality of light-emitting modules, each comprising a power input, a ground, a data input, a data output, a clock input, and a clock output, and connected electrically to said electrical connecting bus terminals.

8. The light-emitting display panel of claim 7, wherein said power input of each said light-emitting module is connected electrically to said first power connecting wire and said second electrical connecting wire; said ground of each said light-emitting module is connected electrically to said first ground connecting wire and said second electrical connecting wire; said data input of each said light-emitting module is connected to said first data connecting wire;
said data output of each said light-emitting module is connected to said second data connecting wire; said clock input of each said light-emitting module is connected to said first clock connecting wire; and said clock output of each said light-emitting module is connected to said second clock connecting wire.

9. The light-emitting display panel of claim 7, further comprising a display frame for fixing said light-emitting display panel, said display frame comprising:
a main module, comprising a post member, a first connecting end, and a second connecting end, said first connecting end and said second connecting end disposed on both ends of said post member;
a control module, disposed inside said post member and connected electrically to said first connecting end and said second connecting end; and
a fixing module, disposed on one side of said main module, comprising a fixing post member, a top frame, and a bottom frame; said fixing post member disposed on one side of said post member; said top frame and said bottom frame fixing both ends of said fixing post member, respectively; said light-emitting display panel sandwiched between said top frame and said bottom frame; and said control module connected electrically to said light-emitting display panel.

10. The light-emitting display panel of claim 9, wherein said first connecting end of each said display frame is connected to said second connecting end of said display frame above, and said control module of said display frame is connected electrically to said control module of said display frame above.

11. The light-emitting display panel of claim 7, wherein said circuit board is flexible.
